(19) United States
(12) Patent Application Publication
(10) Pub. No.: US 2016/0238951 A1
(43) Pub. Date: Aug. 18, 2016

(54) ROLL TO ROLL MASK-LESS LITHOGRAPHY WITH ACTIVE ALIGNMENT

(71) Applicant: APPLIED MATERIALS, INC., Santa Clara, CA (US)

(72) Inventor: John M. WHITE, Hayward, CA (US)

(21) Appl. No.: 15/026,763

(22) PCT Filed: Sep. 24, 2014
(86) PCT No.: PCT/US2014/057120

§ 371 Date: Apr. 1, 2016

Related U.S. Application Data
(60) Provisional application No. 61/894,249, filed on Oct. 22, 2013.

(51) Int. Cl. G03F 7/20; H01L 21/677; H01L 51/00; H01L 21/66; H01L 51/56; H01L 31/18

(52) U.S. Cl. CPC G03F 7/70716; H01L 51/56; H01L 31/1876; H01L 51/0014; H01L 22/20; H01L 21/67742; H01L 2251/5338

(57) ABSTRACT

Embodiments of the present invention relates to apparatus and methods for a maskless lithography on a flexible substrate with active alignment. In one embodiment, a lithography apparatus includes a cylindrical roller rotatable about a central axis and configured to transfer a flexible substrate on a cylindrical substrate supporting surface. A plurality of printing units, each includes an image sensing device and an imaging printing device, may be positioned facing the substrate supporting surface. The plurality of printing units may capture images of pre-existing patterns and/or markers on the flexible substrate as the flexible substrate is being tramsferred continiously and exposure patterns for each printing unit may be adjusted “on-the-fly” according to the captured image, thus achieving active alignment.

### BACKGROUND

1. Field

Embodiments of the present invention generally relate to apparatus and methods for lithographic patterning. More particularly, embodiments of the present invention relates to apparatus and methods for lithographic patterning on flexible substrates.

2. Description of the Related Art

Flexible substrates, such as polymer/plastic substrates, metal foil substrates, are used to fabricate flexible circuits for various applications, such as display, organic light-emitting diodes (OLEDs), and solar cells. However, there are problems in creating a precisely located pattern image on top of an existing patterned layer where there is unavoidable and unpredictable distortion in the pre-existing pattern formed on the flexible substrates. The distortion in the existing pattern is due to inherent inhomogeneity and instability in the flexible substrate material. Such material stretches and shrinks in non-repeatable, non-uniform ways during sequences of deposition, exposure/patterning and etching. As a result, maintaining layer to layer overlay accuracy using conventional lithography is difficult and fine geometry control is almost impossible.

To date there have been several means of patterning on plastic substrates which achieve greater and lesser degrees of success, but always suffering from some sort of compromised performance. One means of patterning multiple layers on a plastic roll material substrate is to use “SAIL” (Self-Aligned Imprint Lithography) technology. SAIL not only compromises the design rules somewhat, but moreover, the patterns that can be created are also limited and force the user to limit the designs of the end products. Another means is to cut the rolls into individual plastic sheets and laminate them to stable substrate material, e.g., glass or metal; then process the laminated materials and delaminate the them when processing is fully completed. However, cutting, laminating, processing and delaminating have increased cost and the inefficiency of the extra steps and the yield losses associated with delaminating. Another means is to simply compromise design rules and accept a lower-grade display quality with large overlay margins. However, comprising design rules cannot satisfy the increased demand for high resolutions.

Therefore, there is a need for improved apparatus and methods for lithographic patterning on flexible substrates.

### SUMMARY

Embodiments of the present invention relates to apparatus and methods for a maskless lithography on a flexible substrate with active alignment.

One embodiment of the present invention provides a lithography apparatus. The lithography apparatus includes a substrate transfer assembly comprising a cylindrical roller rotatable about a central axis and configured to transfer a flexible substrate on a cylindrical substrate supporting surface, and an image printing assembly comprising a plurality of printing units. Each of the plurality of printing units is positioned facing the substrate supporting surface and the plurality of printing units form an arc concentric to the substrate supporting surface.

Another embodiment of the present invention provides an apparatus for lithographic patterning. The apparatus includes a substrate transfer assembly for moving a flexible substrate continuously on a substrate supporting surface, an image printing assembly comprising a plurality of printing units disposed over the printing region and a controller connected with the image printing assembly. Each of the plurality of image units includes an image sensing device, and an image printing device. The controller is configured to perform, for each of the plurality of printing units, receiving and analyzing an image of an upcoming printing area captured by the image sensing device, determining one or more characteristics of the upcoming printing region, generating an exposure pattern from a target pattern and the one or more characteristics of the upcoming printing region, and sending the exposure pattern to the image printing device of the printing unit.

Yet another embodiment of the present invention provides a method for performing maskless lithography. The method includes moving a flexible substrate continuously on a cylindrical substrate supporting surface relative to a plurality of printing units disposed over the cylindrical substrate supporting surface, capturing an image of an upcoming printing region on the flexible substrate for each of the plurality of printing units, determining one or more characteristics of the upcoming printing area from the captured image, generating an exposure pattern from a target pattern and the one or more characteristics of the upcoming printing area, printing the exposure pattern on the upcoming printing region using the corresponding printing unit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic sectional view of a lithography apparatus according to one embodiment of the present invention.

FIG. 1B is a schematic front view of the lithography apparatus of FIG. 1A.

FIG. 1C is a partial flattened side view of the lithography apparatus of FIG. 1A.

FIG. 1D is an enlarged portion of FIG. 1C.

FIG. 2A is a schematic partial perspective view of the lithography apparatus of FIG. 1A showing operation of a first row of printing units.

FIG. 2B is a schematic partial perspective view of the lithography apparatus of FIG. 1A showing operation of a second row of printing units.

FIG. 2C is a schematic partial perspective view of the lithography apparatus of FIG. 1A showing operation of a last row of printing units.

FIG. 3 is a schematic view of a printing unit according to one embodiment of the present invention.

FIG. 4 is a flow chart showing a method according to one embodiment of the present invention.

FIG. 5A is a schematic sectional view of a lithography apparatus according to one embodiment of the present invention.

FIG. 5B is a schematic front view of the lithography apparatus of FIG. 5A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention relates to apparatus and methods for a maskless lithography on a flexible substrate with active alignment. The lithography apparatus according embodiments of the present invention allows for very local (within a few millimeters or less) adjustments in patterning, compensating for variations/distortions in pre-existing patterns on a substrate.

In one embodiment, a lithography apparatus includes a cylindrical roller rotatable about a central axis and configured to transfer a flexible substrate on a cylindrical substrate supporting surface. A plurality of printing units, each includes an image sensing device and an imaging printing device, may be positioned facing the substrate supporting surface. The plurality of printing units may capture images of pre-existing patterns and/or markers on the flexible substrate as the flexible substrate is being transferred continuously and exposure patterns for each printing unit may be adjusted “on-the-fly” according to the captured image, thus achieving active alignment.

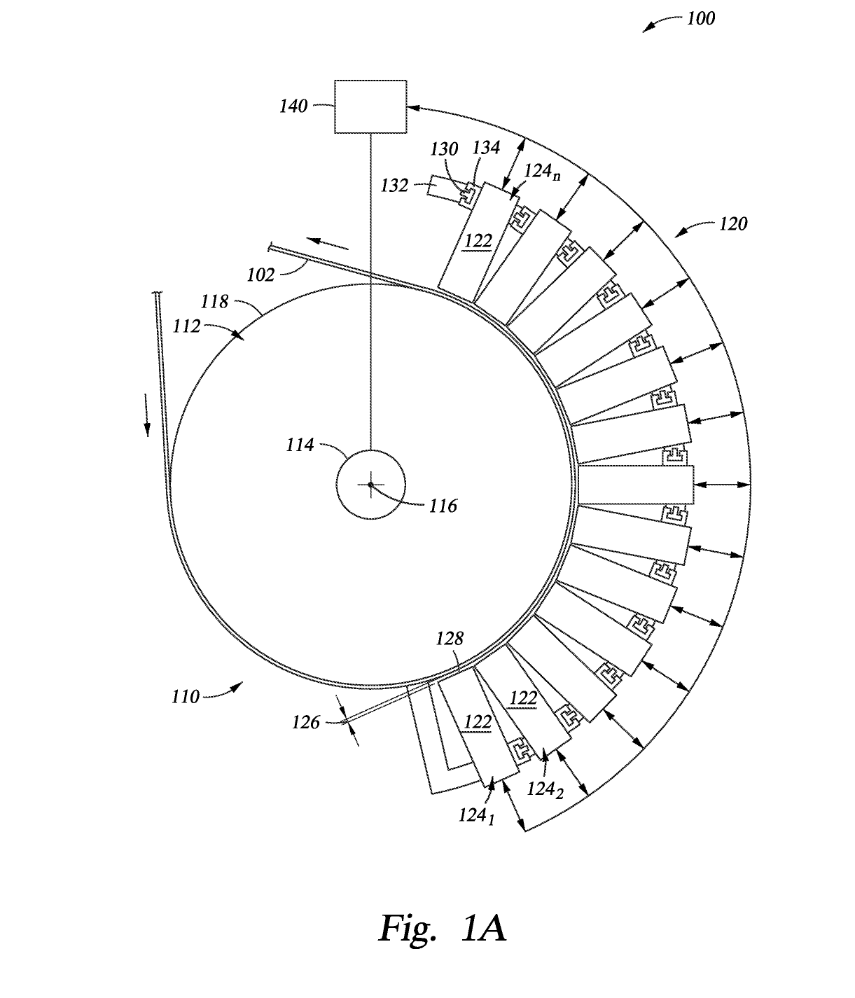

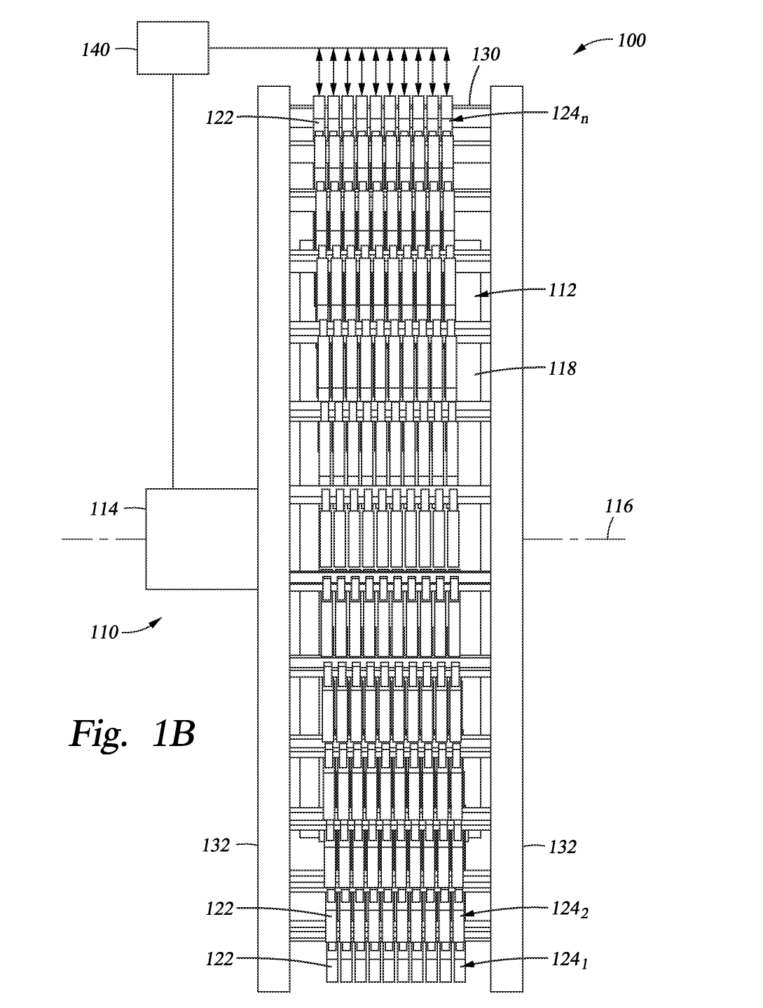

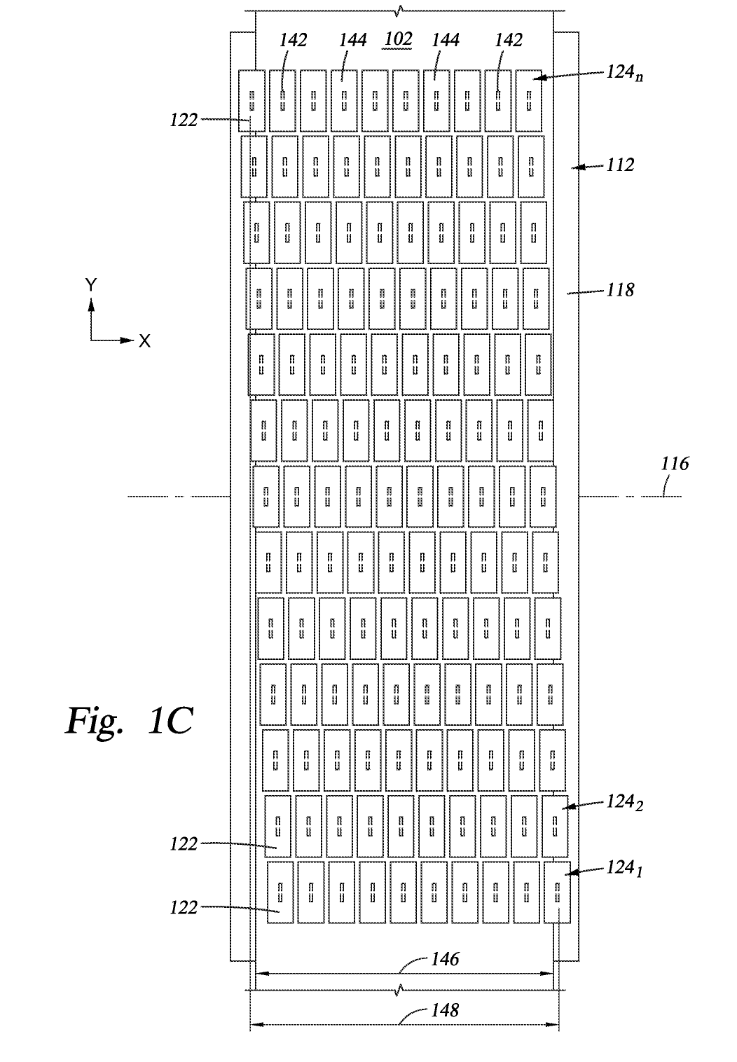

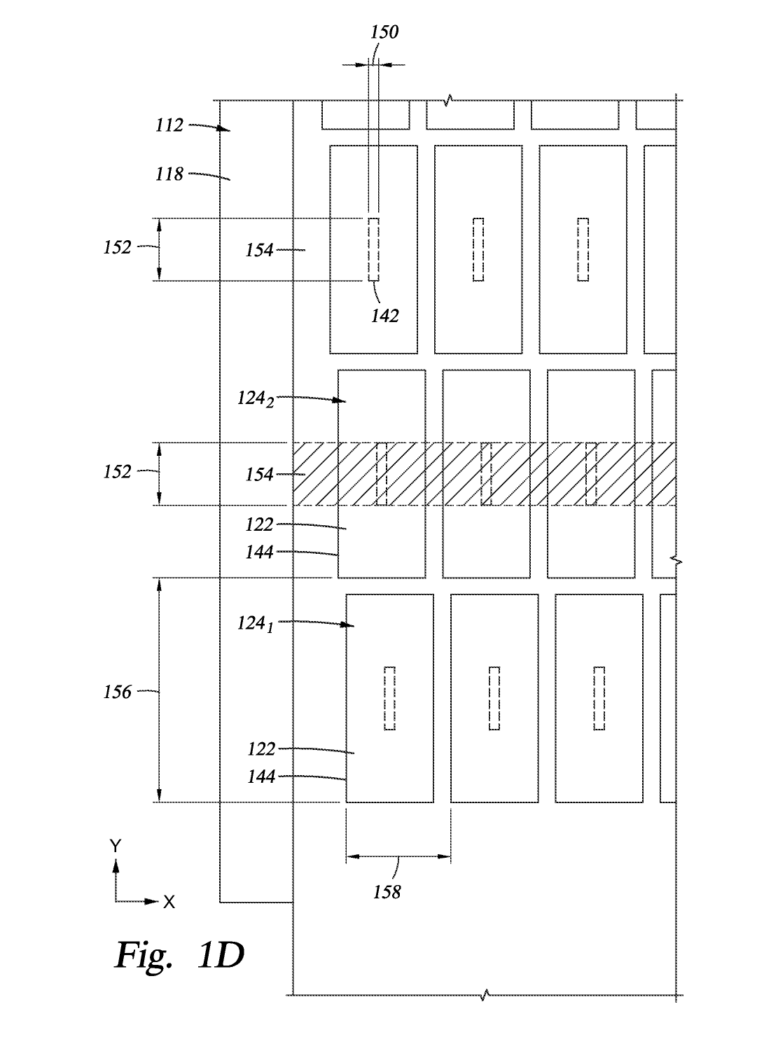

FIG. 1A is a schematic sectional view of a lithography apparatus 100 according to one embodiment of the present invention. FIG. 1B is a schematic front view of the lithography apparatus 100. The lithography apparatus 100 applies mask data patterns on flexible substrates used to forming flexible circuits, such as display, organic light-emitting diodes (OLEDs), solar cells, and the like. The lithography apparatus 100 includes a substrate transfer assembly 110 and an image printing assembly 120. The substrate transfer assembly 110 moves a flexible substrate 102 relative to the imaging printing assembly 120 while the imaging printing assembly 120 prints a pattern on the flexible substrate 102. A system controller 140 may be connected to the image printing assembly 120 and the substrate transfer assembly 110 to facilitate printing one or more layer of patterns on the substrate 102.

The substrate transfer assembly 110 may include a cylindrical roller 112 and a driving unit 114 configured to rotate the cylindrical roller 112 about a central axis 116. An outer surface of the cylindrical roller 112 forms a substrate supporting surface 118. During operation, the flexible substrate 102 contacts and is supported by the substrate supporting surface 118. Particularly, the portion of the flexible substrate 102 being printed by the imaging printing assembly 110 is supported by the substrate supporting surface 118.

The imaging printing assembly 120 includes a plurality of printing units 122 each positioned facing the substrate supporting surface 118. Each of the plurality of printing units 122 is configured to detect an image of a corresponding area of the flexible substrate 102 supported on the substrate supporting surface 118 and print on the flexible substrate 102 a pattern generated according to the detected image. Each of the plurality of printing units 122 is positioned at a fixed distance 126 to the substrate supporting surface 118. Because the flexible substrate 102 contacts the substrate supporting surface 118 while being printed, any distortion of the flexible substrate 102 will not result in distortion of the distance between the flexible substrate 102 and each of the plurality of printing unit 122, thus, improving quality of the printed images by reducing errors in field of depth.

In one embodiment, the fixed distance 126 to the corresponding area on the substrate supporting surface 118 is substantially the same for the plurality of printing units 122 so that the plurality of printing units 122 are arranged in a cylindrical plane concentric to the substrate supporting surface 118.

In one embodiment, the plurality of printing units 122 form a plurality of rows 124₁-124ₙ. Each row 124₁-124ₙ includes multiple printing units 122 linearly aligned along the direction parallel to the central axis 116 of the cylindrical roller 112. The plurality of rows 124₁-124ₙ are disposed parallel to one another. The multiple printing units 122 in each row 124₁-124ₙ may be positioned at equal distance. The number of imagining units 122 in each row 124₁-124ₙ may be the same. The printing units 122 among the plurality of rows 124₁-124ₙ may be aligned in a staggered manner along the axial direction parallel to the central axis 116. The staggered alignment of the plurality of rows 124₁-124ₙ allows each printing unit 122 to print on a different area on the flexible substrate 102 and the plurality of rows 124₁-124ₙ of printing units 122 cover an entire strip traversing the flexible substrate 102.

In one embodiment, the plurality of printing units 122 may be mounted on guide bars 130 attached to a frame 132. Each guide bar 130 may be parallel to the central axis 116 and support one row of printing units 122. Locations of the printing units 122 along each guide bar 130 may be adjusted together or individually to achieve desired alignment of the imagining units 122.

Each of the plurality of printing units 122 are connected to the system controller 122. During operation, the cylindrical roller 112 rotates at a substantially constant rate to transfer the flexible substrate 102 relative to the printing assembly 120. Each printing unit 122 may periodically capture an image of the corresponding surface area of the flexible substrate 102 being transferred by the cylindrical roller 112. The captured image, including markers, patterns, or other surface features, may be transferred to the system controller 140. The system controller 140 analyzes the captured image to determine characteristics of an upcoming printing area for the particular image unit 122. For example, the system controller 140 may determine a coordinate, amount of distortion, amount of wandering, or other characteristics of the upcoming printing area. Based on the determined characteristics, the system controller 140 generates an exposure pattern for the printing unit 122, and sends the exposure pattern to the printing unit 122. The printing unit 122 prints the printing pattern upon receiving the exposure pattern.

FIG. 1C is a partial flattened side view of the lithography apparatus 100 showing the arrangement of the plurality of printing units 122 and the relative positions of the plurality of printing unit 122 and the substrate supporting surface 118. FIG. 1D is an enlarged portion of FIG. 1C. In FIG. 1C, the cylindrical substrate supporting surface 118 is flattened on an x-y plane for clarity. The x axis parallels to the central axis 116 of the cylindrical roller 112. The y axis traverses the x axis and represents the direction the flexible 102 is transferred by the cylindrical roller 112 during operation.

Each of the plurality of printing units 122 has a footprint 144 and a printing region 142. FIG. 1C schematically shows that the printing region 142 is located in one corner of the footprint 144 for clarity of illustration. The printing region 142 may be located in other positions. Because the printing unit 122 generally scales down the printed image to achieve high resolution, the printing region 142 is generally smaller than the footprint 144 for each printing unit 122. Each printing region 142 may have a printing width 150 along the x direction and a printing length 152 along the y direction. For a substrate having a substrate width 146, at least a number N of printing units 122 may be used to print a band 254 having a printing length 152 traversing the flexible substrate 102 while the flexible substrate 102 moves mono-directionally along the y direction, where N may be calculated by:

$$N \geq \frac{substrate width 146}{printing width 150} . \qquad Equation 1$$

Because the footprint 144 of the printing units 122 is larger than the printing region 142, the at least N printing units 122 may be arranged in a plurality of parellel rows 124₁-124ₙ for printing on the entire region in the band 254. Each row 124₁-124ₙ may include multiple printing units 122 distributed along the x direction. The printing areas 142 of the multiple printing units 122 in each row 124 may have the same y coordinate and different x coordinate in the x-y plane. The printing units 122 in different rows 124₁-124ₙ being staggered so that printing units 122 in different rows 124 do not print on the same areas when the flexible substrate 102 passes by. Each of the plurality of printing units 122 may have a printing area 142 starting at a unique x coordinate.

In one embodiment, the printing area 142 of one printing unit 122 may overlap with the printing area(s) 142 of printing unit(s) 122 designated to print neighboring area(s) to ensure that the entire width of the flexible substrate 102 is covered by the printing units 122. In one embodiment, the plurality of printing unit 122 may be arranged so that neighboring printing regions 142 overlap with one another at between about ______ % to ______ % of the printing width 150.

In one embodiment, a total printing width 148 covered by the plurality of printing units 122 may be greater than the substrate width 146 to tolerate any wanderings of the flexible substrate 102 during operation. Wandering refers to lateral shifting of the flexible substrate 102 in the x direction when the flexible substrate 102 is being transferred by the cylindrical roller 112.

As shown in FIG. 1C, the multiple printing units 122 in every row 124₁-124ₙ are arranged in equal unit spacing 158, and the plurality of rows 124₁-124ₙ are positioned in equal row spacing 156. Each of the plurality of rows 124₁-124ₙ is shifted towards the right compared to the row 124₁-124ₙ upstream. The amount of shifting between neighboring rows may be about the printing width 150 minus an overlapping width. The number m of printing units 122 in each row 124 may be determined by:

$$N \geq \frac{total printing width 148}{unit spacing 158} . \qquad Equation 2$$

The number n of rows 124 may be determined by:

$$N \geq \frac{unit spacing 158}{printing width 150 * ( 1 - percentatge of overlap )} . \qquad Equation 3$$

Thus, the total n times m of printing unit 122 may be used in the image printing assembly 120.

The amount of row spacing 156 may be arranged to be multiple times of the printing length 152 of each printing unit 122 for the imaging printing assembly 120 to efficiently cover the entire length (along the y direction) of the flexible substrate 102.

During operation, the cylindrical roller 112 rotates at a substantially constant angular speed to transfer the flexible substrate 102 at a substantially constant linear speed relative to the image printing assembly 120. The image printing assembly 120 of the lithography apparatus 100 may remain stationary during operation. The linear speed of the flexible substrate 102 relative to the imaging printing assembly 120 may be selected according to process speed of the printing unit 122 and the system controller 140 so that the flexible substrate 102 can be printed while moving at a constant linear speed relative to the imaging printing assembly 120. In one embodiment, the flexible substrate 102 may travel at a speed of about 200-300 mm/minute relative to the imaging printing assembly 120. While the flexible substrate 102 is being transferred, the band 154 on the flexible substrate 102 travels along the y direction sequentially aligning with each row 124₁-124ₙ When aligned with a row 124 of printing units 122, a portion of the band 154 is printed by the row 124 of printing units 122. When the band 154 travels passed the last row 124ₙ, the band 154 across the entire substrate width 146 is printed. The imaging printing assembly 120 prints patterns on the flexible substrate 102 band by band as the flexible substrate 102 passes by. In one embodiment, the imaging printing assembly 120 may be configured to print band by band at a slightly overlapped manner to ensure the flexible substrate 102 receives continuous coverage length wise.

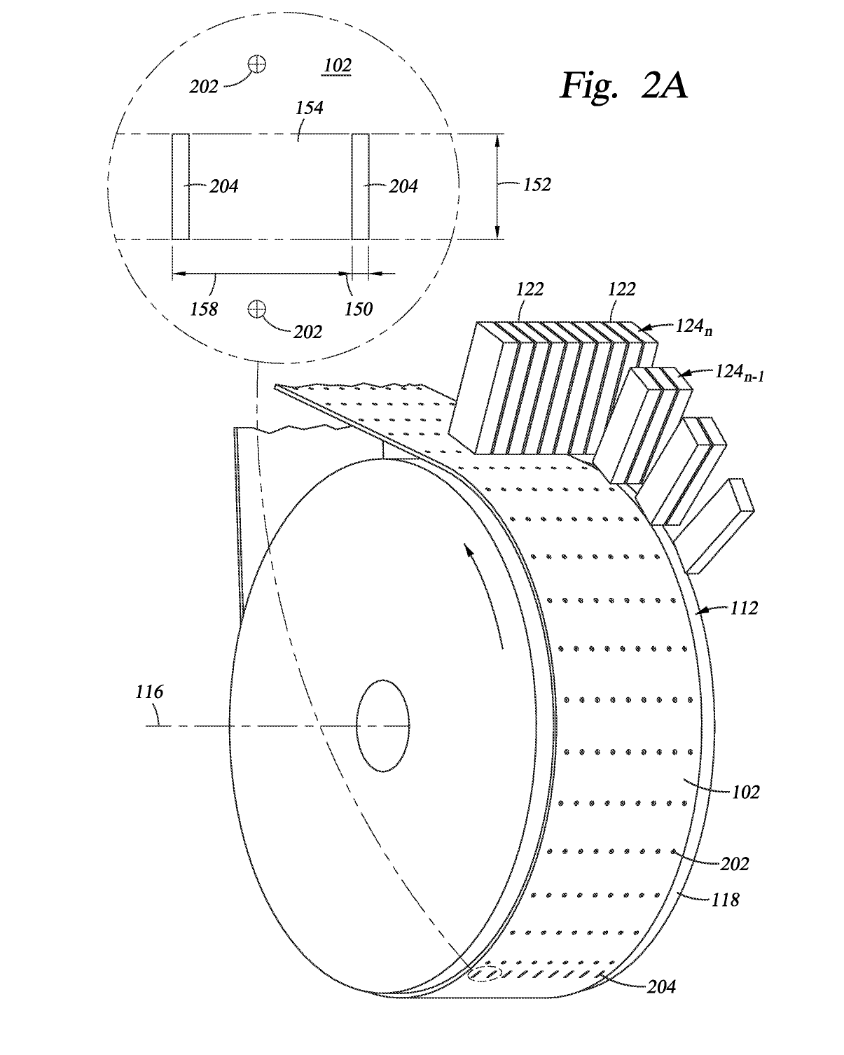

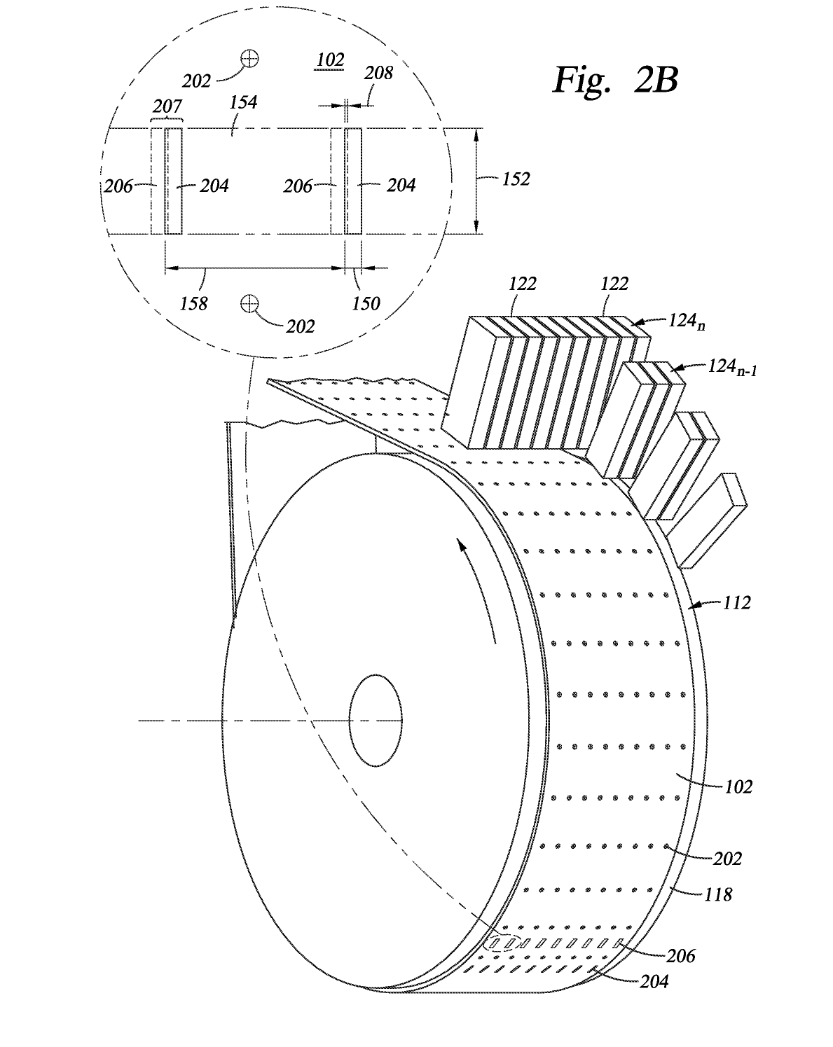

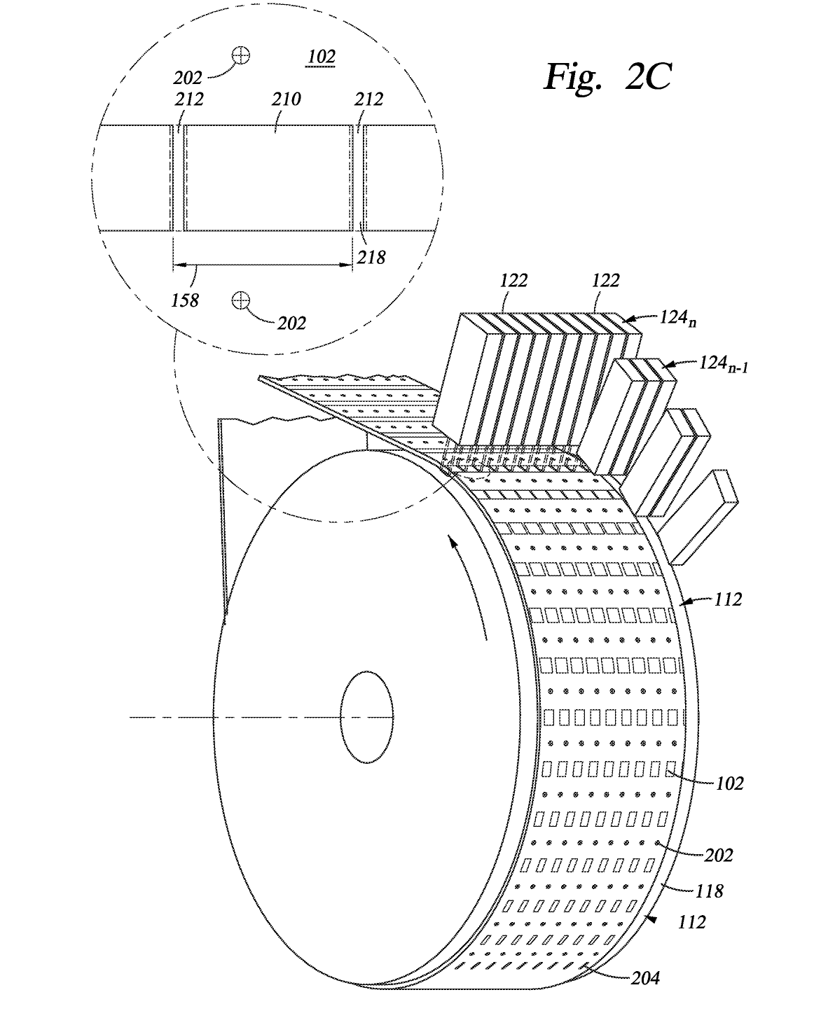

FIGS. 2A-2C schematically illustrates a sequence of the band 154 of flexible substrate being printed by the lithography apparatus 100 of FIGS. 1A-1C. FIG. 2A is a schematic partial perspective view of the lithography apparatus 100 showing the band 154 of the flexible substrate 102 being printed by the first row 124₁ of the printing units 122. Only the first row 124₁ of the printing units 122 are shown in FIG. 2A for clarity. While the band 154 aligns with the first row 124₁ of the printing units 122, each printing unit 122 in the first row 124₁ prints in a first region 204 in the band 154. The multiple first regions 204 are spaced apart by the unit spacing 158 of the printing units 122 in the first row 124₁.

In one embodiment, the flexible substrate 102 may include optional markers 202. The markers 202 may be used by the lithography apparatus 100 to determine characteristics of the flexible substrate 102. For example, the lithography apparatus 100 may determine position, distortion, and/or wandering of the flexible substrate 102 near the band 154 from a captured image of the markers 202. Alternatively, the lithography apparatus 100 may determine characteristics of the flexible substrate 102 near the band 154 from a captured image of the existing image/pattern on the flexible substrate 102.

FIG. 2B is a schematic partial perspective view of the lithography apparatus 100 showing the band 154 of the flexible substrate 102 being printed by the second row 124₂ of the printing units 122. Only the second row 124₂ of the printing units 122 are shown in FIG. 2B for clarity. While the band 154 aligns with the second row 124₂ of the printing units 122, each printing unit 122 in the second row 124₂ prints in a second region 206 in the band 154. The multiple second regions 206 are spaced apart by the unit spacing 158 of the printing units 122 in the second row 124₂. Each second region 206 may overlap with a corresponding first region 204 by an overlapping strip 208. Each second region 206 joins with the corresponding first region 204 to form a joined region 207. After the second row 124₂ finishes printing, the band 154 have multiple joined region 207 that are printed and are at unit spacing 158 apart.

While the band 154 travels from the position aligning with the first row 124₁ to the position aligning with the second row 124₂, additional bands 154′, 154″ may sequentially align with and be printed by the first row 124₁ when the row spacing 156 is larger than the printing width 150 of each printing unit 122. FIG. 2B illustrates that bands 154, 154′, 154″ are spaced apart. Alternatively, the bands 154, 154′, 154′ may be joined together with overlapping regions to satisfy process requirements, for example to print patterns larger than the printing length 152 of one printing unit 122.

FIG. 2C is a schematic partial perspective view of the lithography apparatus 100 showing the band 154 of the flexible substrate 102 being printed by the nth row and last row 124ₙ of the printing units 122. Only the last row 124ₙ of the printing units 122 are shown in FIG. 2C for clarity. Before arriving at the position that aligns with the last row 124ₙ , the band 154 has been printed by the previous n-1 rows 124₁, 124₂, . . . . 124ₙ₋₁ with multiple joined regions 210 spaced at equal distance apart. While the band 154 aligns with the last row 124ₙ of the printing units 122, each printing unit 122 in the last row 124ₙ prints in a last region 212 in the band 154. Each last region 210 overlaps with adjacent joined region(s) 210 closing any unprinted gaps in the band 154. After the last row 124ₙ finishes printing, the entire band 154 on the flexible substrate 102 has been printed.

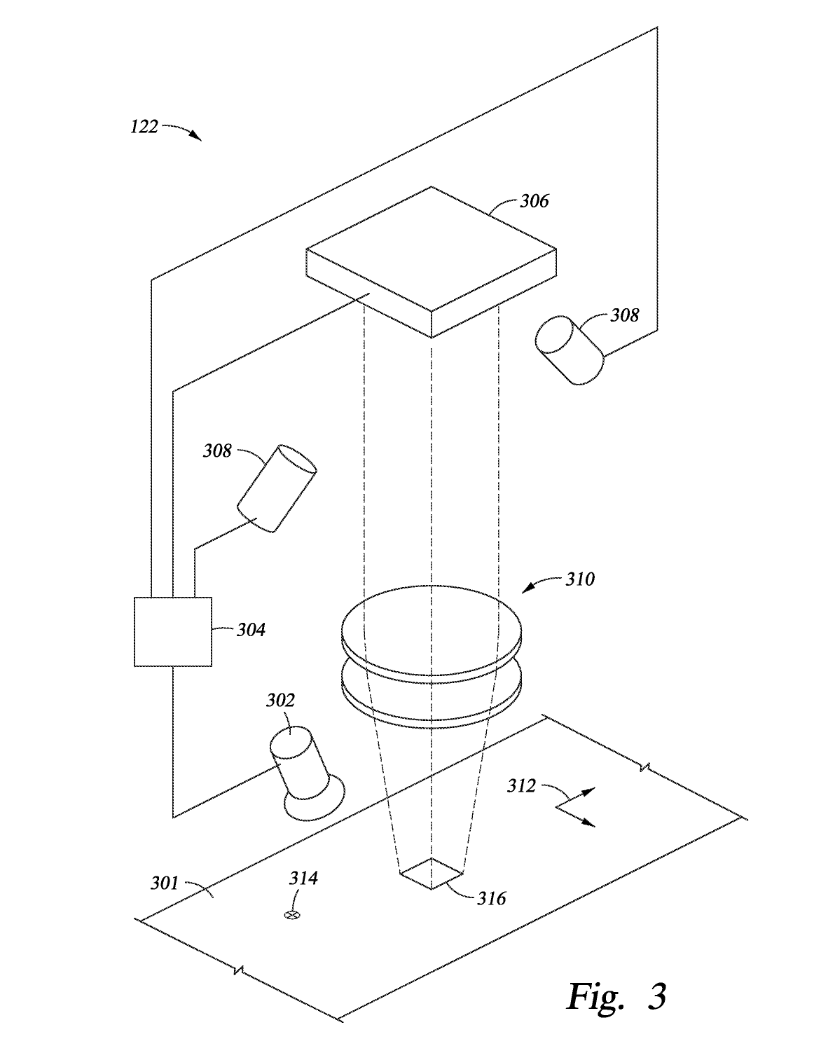

Each printing unit 122 in the lithography apparatus 100 is configured to capture images of or near a printing region and to print a generated pattern without using a mask. FIG. 3 is a schematic view of the printing unit 122 according to one embodiment of the present invention.

The printing unit 122 includes an image sensing device 302 and an image printing device 303. The image sensing device is directed towards a printing area to capture an image of a portion of a printing plane 312. The image printing device 303 is positioned to print a pattern on a portion of the printing plane 312. The image sensing device 302 may be a CCD (charged-coupled device) camera. The image sensing device 302 is connected to a printing image controller 304. The printing image controller 304 receives and analysis the captured images from the image sensing device 302. The printing image controller 304 may be connected to and provide control to the plurality of printing units 122. In one embodiment, the printing image controller 304 may be part of a system controller of a lithography apparatus, such as the system controller 140.

The image printing device includes a DMD (digital mirror device) 306, and one or more light sources 308 directed to the DMD 306. The DMD 306 may include an array of micro mirrors. Each micro mirror may be switched between an ON position and an OFF position. At the ON position, the micro mirror reflects the light from the light source 308 while at the OFF position, the micro mirror does not reflect the light from the light source 308. Each micro mirror may represent one pixel in a binary image. By switching individual micro mirrors between ON and OFF positions, the DMD 306 may project a pattern of binary image towards the printing plane 312 so that the pattern may be printed on a substrate 301 positioned on the printing plane 313. In one embodiment, optics 310 may be positioned between the DMD 306 and the printing plane 312 to reduce the size of the binary image and increase resolution of the printed pattern.

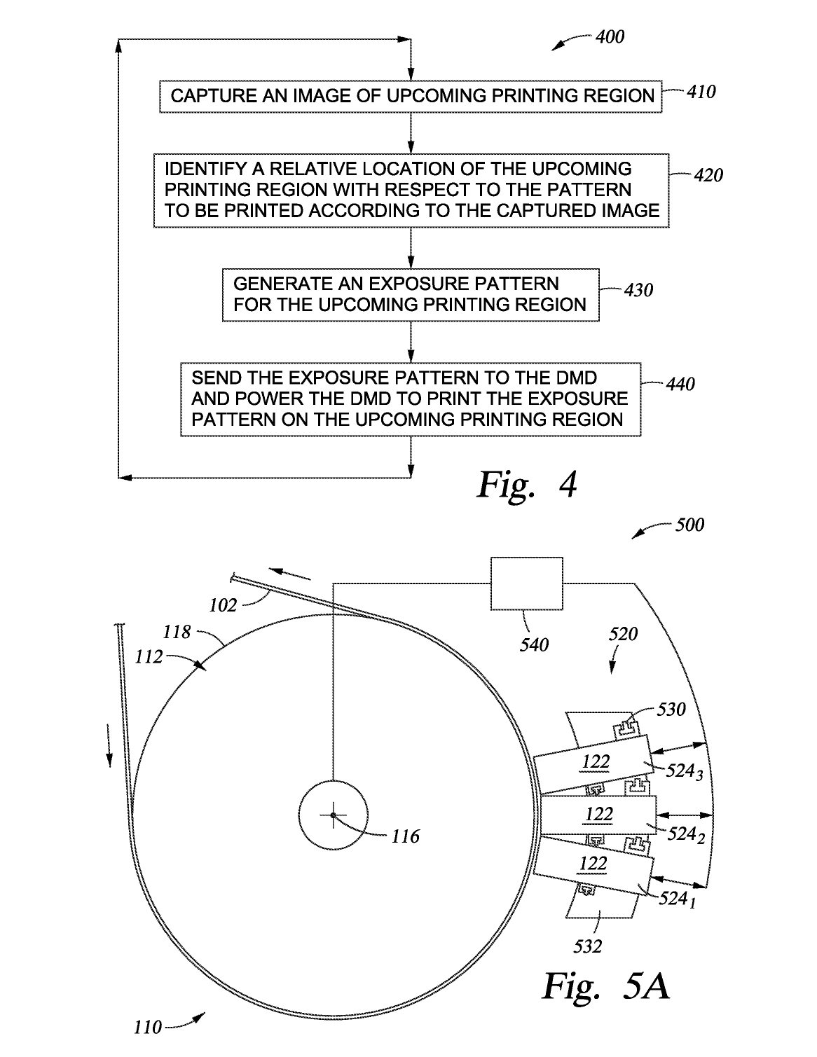

FIG. 4 is a flow chart showing a method 400 for printing a maskless pattern on a substrate using the printing unit 122 according to one embodiment of the present invention.

In Box 410, the camera 304 of the printing unit 122 may capture an image of upcoming printing region on the substrate to be printed and send the captured the image to the printing image controller 304. The upcoming printing region may have one or more features such as markers and pre-existing pattern.

In Box 420, the captured image may be analyzed to determine one or more characteristics of the upcoming printing region on the substrate by the printing image controller 304. In one embodiment, analyzing the captured image may include indentify a location of the upcoming printing region on the substrate with respect to a target pattern to be printed by the printing unit 122. The relative location may be determined by one or more marks and/or the pre-existing pattern on the upcoming printing region captured in the image. In one embodiment, additional features characteristics, such as amount of wandering, degree of distortions along different directions, may be determined from the captured image.

In Box 430, an exposure pattern may be generated from the target pattern and the determined one or more characteristics of the upcoming printing region. Box 430 may be performed by the printing image controller 304. In one embodiment, generating the exposure pattern may include cropping a portion of the target pattern that would fit in the upcoming printing region based on the determined relative location. In another embodiment, generating the exposure pattern may further include modifying the target pattern according to the amount of wandering and/or distortion.

In Box 440, the exposure pattern is sent to the DMD 306 for printing. The array of micro mirrors in the DMD 306 may be switched to ON or OFF position according to the exposure pattern. The light source 308 may be powered and the light reflected by DMD 306 projected to the printing region to print the exposure pattern thereon.

Box 410 to Box 440 may be repeated when the substrate 301 moves continuously relative to the printing unit 122. For example, in the lithography apparatus 100, each of the plurality of printing units 122 may repeatedly perform Box 410 to Box 440 to print a pattern on the flexible substrate 102 which continuously moves relative to the printing units 122.

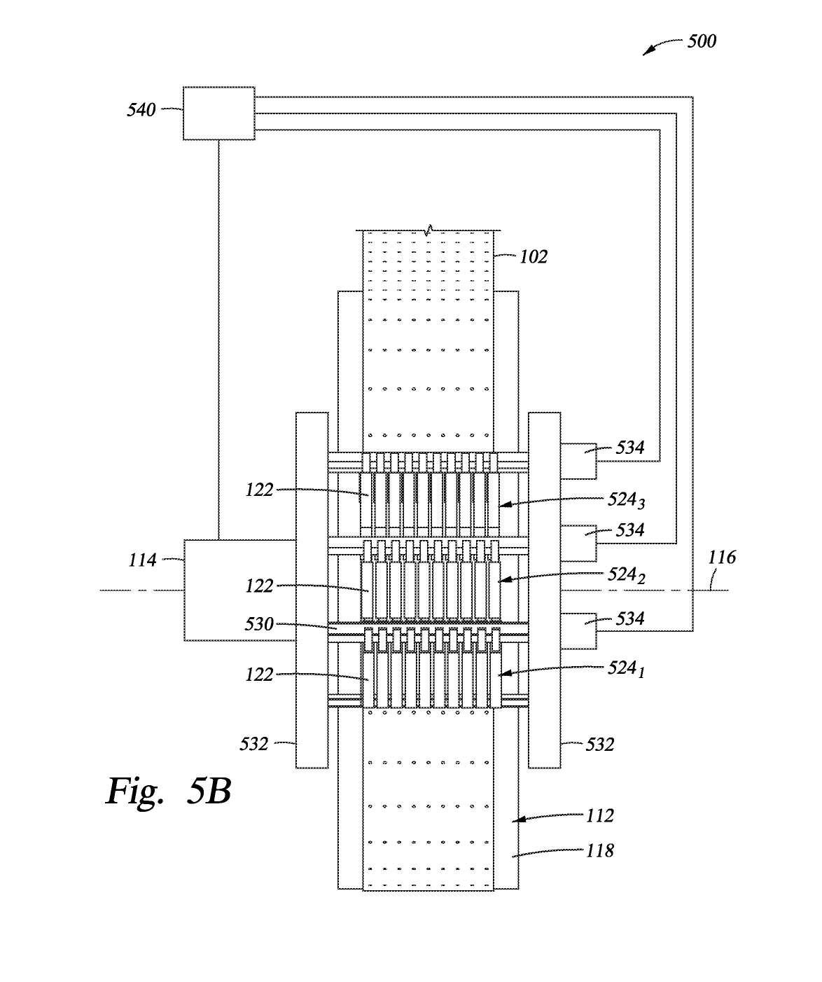

FIG. 5A is a schematic sectional view of a lithography apparatus 500 according to another embodiment of the present invention. FIG. 5B is a schematic front view of the lithography apparatus 500. The lithography apparatus 500 is similar to the lithography apparatus 100 except that the lithography apparatus 100 includes enough number of printing units that allow a full continuous operation while the lithography apparatus 500 includes shifting mechanism and reverse substrate motion to allow a step by step operation using fewer printing units.

The lithography apparatus 500 includes the substrate transfer assembly 110 as described with FIGS. 1A-1B. A system controller 540 may send control signal to the driving unit 114 to rotate the cylindrical roller 112 back and forth so that the flexible substrate 102 may be transferred both forwards and backwards.

The lithography apparatus 500 includes an imaging printing assembly 520 having a plurality of printing units 122 each positioned facing the substrate supporting surface 118. The plurality of printing units 122 may be arranged in at least one row 524 along the direction of the central axis 116 of the cylindrical roller 112. In the imaging printing assembly 520, the total number of printing units 122, total rows of printing units 122 and/or number of printing units 122 in each row may be less than the minimum numbers calculated according to Equations 1-3. The reduced numbers may be selected to reduce costs of a large number of printing units, limited by the space available for the minimum numbers of printing units due to factors such as smaller diameter of the cylindrical roller or higher resolution requirement. Three rows 524₁, 524₂, 524₃ of printing units 122 are shown in the example of FIGS. 5A-5B. However, the number of rows may be varied depending on one or more factors, such as cost, space available, dimension of the cylindrical roller, or resolution requirements.

Each row 524₁, 524₂, 524₃ is similar to the rows 124 of printing units 122 of the lithography apparatus 100 described above except that the printing units 122 in each row 524₁, 524₂, 524₃ may be shifted along the direction parallel to the central axis 116 during operation. In one embodiment, the printing units 122 in each row 524₁, 524₂, 524₃ may be arranged in equal spacing and being shifted in unison to maintain the equal spacing. Alternatively, spacings between neighboring printing units 122 in each row 524₁, 524₂, 524₃ may be variously arranged according to processing requirement and each printing unit 122 may be shifted individually.

Each row 524₁, 524₂, 524₃ of printing units 122 may be mounted on a perspective guide bar 530 attached to a frame 532. The guide bars 530 are positioned substantially parellel to the central axis 116. In one embodiment, each printing units 122 may be attached to the guide bar 530 by a linear bearing. A shifting actuator 534 may be attached to each guide bar 530 to move the plurality units 122 along the guide bar 530 to shift positions of the plurality units 122. In the embodiment of FIG. 5B, the shifting actuator 534 is configured to move the printing units 122 in unison. Alternatively, each printing unit 122 may be attached to one shifting actuator and being shifted individually.

In addition to analyzing captured images of the flexible substrate 102 from the printing units 122 and generating exposure patterns according to the captured images as the system controller 140 does, the system controller 540 also controls and synchronizes the rotating direction and/or speed of the cylindrical roller 122 and the shifting of the plurality of rows 524₁, 524₂, 524₃.

During operation, the cylindrical roller 112 first rotates forward at a substantially constant rate to transfer the flexible substrate 102 relative to the image printing assembly 520 so that a band on the flexible substrate 102 may be printed by all of the rows 524₁, 524₂, 524₃of the printing unit 122. After the band being printed passes all the rows 524₁, 524₂, 524₃ for the first time, the band is only partially printed because the number of printing units 122 in the image printing assembly 520 is less than the number of printing units 122 required to cover the entire width of the flexible substrate 102.

The cylindrical roller 112 then rotates backward to transfer the band to be upstream to the first row 524₁ once more. The rows 524₁, 524₂, 524₃of printing units 122 may be shifted so that each printing unit 122 aligns with a region in the band that is not previously printed.

Next, the cylindrical roller 112 rotates forward again to transfer the band of flexible substrate 102 at a substantially constant linear speed to so that the band can pass the rows 524₁, 524₂, 524₃ and being printed again.

The flexible substrate 102 may be transferred back and forth multiple times until the entire width of the band is printed. The cylindrical roller 112 may then rotate forward again to start the same printing process for next band of flexible substrate.

Even though apparatus and methods for maskless lithography are discussed in the examples above, embodiments of the present invention may be used in any application which requires similar “on-the-fly” exposure control.

While the foregoing is directed to embodiments of the present invention, other and further embodiments of the invention may be devised without departing from the basic scope thereof, and the scope thereof is determined by the claims that follow.

1. A lithography apparatus, comprising:
a substrate transfer assembly comprising a cylindrical roller rotatable about a central axis and configured to transfer a flexible substrate on a cylindrical substrate supporting surface; and
an image printing assembly comprising a plurality of printing units, wherein each of the plurality of printing units is positioned facing the substrate supporting surface, and the plurality of printing units form an arc concentric to the substrate supporting surface.

2. The apparatus of claim 1, wherein the plurality of printing units form one or more rows substantially parallel to the central axis of the cylindrical roller.

3. The apparatus of claim 2, wherein the plurality of printing units form a plurality of rows substantially parallel to the central axis of the cylindrical roller, each row comprises multiple printing units, and the printing units in the plurality of rows are arranged in staggered manner.

4. The apparatus of claim 3, wherein the imaging printing assembly further comprises:
a frame; and
a plurality of guide bars mounted on the frame and substantially parellel to the central axis of the cylindrical roller, wherein each guide bar supports a row of printing units.

5. The apparatus of claim 4, wherein the multiple printing units in each row are positioned at equal spacing.

6. The apparatus of claim 2, wherein the imaging printing assembly further comprises:
a frame; and
one or more guide bars mounted on the frame and substantially parellel to the central axis of the cylindrical roller, wherein the plurality of printing units are movably coupled to the one or more guide bars.

7. An apparatus for lithographic patterning, comprising:
a substrate transfer assembly for moving a flexible substrate continuously on a substrate supporting surface;
an image printing assembly comprising a plurality of printing units disposed over the printing region, wherein each of the plurality of image units comprises:
an image sensing device; and
an image printing device; and
a controller connected with the image printing assembly, wherein the controller is configured to perform, for each of the plurality of printing units:
receiving and analyzing an image of an upcoming printing area captured by the image sensing device;
determining one or more characteristics of the upcoming printing region;
generating an exposure pattern from a target pattern and the one or more characteristics of the upcoming printing region; and
sending the exposure pattern to the image printing device of the printing unit.

8. The apparatus of claim 7, wherein the substrate transfer assembly comprises a cylindrical roller rotatable about a central axis and configured to transfer a flexible substrate on a cylindrical substrate supporting surface, and the plurality of printing units form an arc radially outward of the substrate supporting surface.

9. The apparatus of claim 8, wherein the plurality of printing units are arranged so that printing areas of the plurality of printing units cover an entire width of the flexible substrate.

10. The apparatus of claim 9, wherein the plurality of printing units are arranged in a plurality of rows parallel to the central axis and each row comprises multiple printing units.

11. The apparatus of claim 10, wherein the multiple printing units in each row are arranged at equal spacing, and the printing units are staggeredly arranged from row to row.

12. A method for performing maskless lithography, comprising:
moving a flexible substrate continuously on a cylindrical substrate supporting surface relative to a plurality of printing units disposed over the cylindrical substrate supporting surface;
capturing an image of an upcoming printing region on the flexible substrate for each of the plurality of printing units;
determining one or more characteristics of the upcoming printing area from the captured image;
generating an exposure pattern from a target pattern and the one or more characteristics of the upcoming printing area; and
printing the exposure pattern on the upcoming printing region using the corresponding printing unit.

13. The method of claim 12, wherein determining one or more characteristics comprises indentifying a location of the upcoming printing region on the flexible substrate with respect to the target pattern.

14. The method of claim 13, wherein identifying the location comprising determining the location according to a pre-existing pattern shown in the captured image or according to markers shown in the captured image.

15. The method of claim 12, further comprising:
reversing the flexible substrate backwards after a band of the flexible substrate passes the plurality of printing units;
adjusting locations of the plurality of printing units along the direction of the central axis to align the plurality of printing units with not printed regions in the band; and
repeating the moving, capturing, determining, generating and printing.
